(19) United States
(12) Patent Application Publication
(10) Pub. No.: US 2026/0247522 A1
(43) Pub. Date: Aug. 20, 2026

(54) PRINTED CIRCUIT BOARD HARDWARE INTERFACE WITH REDUCED CROSSTALK

(71) Applicant: Microsoft Technology Licensing, LLC, Redmond, WA (US)

(72) Inventor: Gong OUYANG, Redmond, WA (US)

(73) Assignee: Microsoft Technology Licensing, LLC, Redmond, WA (US)

(21) Appl. No.: 19/057,856

(22) Filed: Feb. 19, 2025

(51) Int. Cl. H05K 1/02; H05K 1/11

(52) U.S. Cl. CPC H05K 1/0228; H05K 1/114; H05K 2201/09227; H05K 2201/0939; H05K 2201/09409; H05K 2201/09418; H05K 2201/09636; H05K 2201/10212; H05K 2201/10719

(57) ABSTRACT

A hardware interface includes a printed circuit board (PCB), including a plurality of PCB dog-bone structures electrically connecting a plurality of PCB vias to a corresponding plurality of socket pins. Each PCB dog-bone structure includes a respective PCB, an intermediary trace, and a socket interface pad electrically connected to a respective socket pin. The plurality of PCB dog-bone structures includes first and second PCB dog-bone structures, which respectively include first and second PCB vias and socket interface pads. The first socket interface pad is adjacent to the second socket interface pad, and the first PCB via is adjacent to the second PCB via. The first socket interface pad and the second socket interface pad are arranged parallel to a first direction, and the first PCB via and the second PCB via are arranged parallel to a second direction, different from the first direction.

### BACKGROUND

Electronic devices may include hardware interfaces for connecting a printed circuit board (PCB) with an external hardware chip, such as a central processing unit (CPU), through an array of electrical connections. For instance, such configurations may include structured arrangements of PCB vias, socket pins, electrical traces, and conductive interface pads.

### SUMMARY

A hardware interface includes a printed circuit board (PCB), including a plurality of PCB dog-bone structures electrically connecting a plurality of PCB vias to a corresponding plurality of socket pins. Each PCB dog-bone structure includes a respective PCB, an intermediary trace, and a socket interface pad electrically connected to a respective socket pin. The plurality of PCB dog-bone structures includes first and second PCB dog-bone structures, which respectively include first and second PCB vias and socket interface pads. The first socket interface pad is adjacent to the second socket interface pad, and the first PCB via is adjacent to the second PCB via. The first socket interface pad and the second socket interface pad are arranged parallel to a first direction, and the first PCB via and the second PCB via are arranged parallel to a second direction, different from the first direction.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 schematically shows an example electronic device including a printed circuit board (PCB) communicatively coupled with a hardware chip through a hardware interface.

FIGS. 2A and 2B schematically depict example PCB dog-bone structures of a hardware interface.

FIGS. 3A and 3B schematically illustrate spatial relationships between PCB vias and socket interface pads of a plurality of PCB dog-bone structures.

FIGS. 4A-4C illustrate electromagnetic interference between adjacent pairs of socket pins and PCB vias of a hardware interface.

FIG. 5 schematically illustrates a plurality of columns of PCB vias, including signal via columns and ground via columns.

FIG. 6 schematically shows an example computing system.

### DETAILED DESCRIPTION

Electronic devices may be communicatively coupled with any of a wide variety of different hardware chips using suitable hardware interfaces. For instance, a printed circuit board (PCB) may include a hardware interface enabling it to be connected to an external hardware chip (e.g., such as a central processing unit (CPU)) through an array of electrical connections, thereby facilitating communication between the hardware chip and various components of the electronic device. Such hardware interfaces may include a plurality of conductive structures, such as PCB vias, conductive traces, conductive pads, socket pins, etc.

However, the proximity of these various interface components to one another can cause electromagnetic crosstalk that interferes with signal transmission. For instance, electrical signal flowing through one socket pin may create an electromagnetic field that affects a neighboring socket pin, potentially changing the signals flowing between the PCB and the hardware chip. Furthermore, such crosstalk may arise at multiple different points within the hardware interface, and these different sources of crosstalk may be additive, meaning the total amount of signal interference may be proportional to these different sources of crosstalk added together. For instance, crosstalk may be exhibited between adjacent socket pins, adjacent PCB vias, PCB traces that are routed in proximity to PCB vias, etc., and these different sources may be correlated with one another in both phase and magnitude. As such, these different sources may cumulatively increase the total amount of signal interference between the PCB and the hardware chip.

Accordingly, the present disclosure describes example configurations for a hardware interface that includes a plurality of PCB dog-bone structures. The arrangement of these PCB dog-bone structures may improve the quality of the signal transmission between the hardware chip and the PCB, by reducing total signal interference caused by electromagnetic crosstalk between neighboring interface components. Each PCB dog-bone structure includes a socket interface pad and a PCB via, which are connected by an intermediary trace. The socket interface pads each correspond to socket pins that contact an external hardware chip—e.g., by touching respective conductive contacts on the surface of the hardware chip. In this manner, the hardware interface establishes a communication pathway between the hardware chip and the PCB through the PCB-dog-bone structures.

More particularly, according to the arrangements described herein, the plurality of PCB dog-bone structures include a first PCB dog-bone structure and a second PCB dog-bone structure. These respectively include first and second socket interface pads and first and second PCB vias, each connected via intermediary traces. However, the first and second socket interface pads are arranged along a first direction (e.g., forming a row parallel to a horizontal axis), and their respective PCB vias are arranged along a second direction, different from the first direction (e.g., forming a column perpendicular to the horizontal axis). In certain implementations, the first and second PCB vias form a differential signal pair configured to propagate complementary signals. As will be described in more detail below, using this arrangement, pin-to-pin electromagnetic crosstalk exhibited between adjacent socket pins may have an opposite polarity to the via-to-via electromagnetic crosstalk exhibited between adjacent PCB vias. These sources of crosstalk may at least partially cancel one another out, decreasing the total amount of signal interference and improving overall transmission quality, as compared to other arrangements where the different sources of crosstalk have the same polarity.

By arranging PCB dog-bone structures in this manner, the disclosed techniques provide several technical advantages. For instance, as discussed above, electromagnetic crosstalk that arises between neighboring socket pins may have the opposite polarity from the crosstalk that arises between neighboring PCB vias. Such a configuration may improve the signal-to-noise ratio (SNR) and reduce the bit-error rate (BER) of data communication between the PCB and hardware chip. Furthermore, as will be described in more detail below, the PCB vias may be divided into a plurality of columns. Some of these columns may be referred to as “signal via columns,” as they include PCB vias that carry signals transmitted to and/or received from the hardware chip. Other columns may be referred to as “ground via columns,” as they include PCB vias used to provide an electrical grounding path to a ground layer of the PCB. Each signal via column may be neighbored by at least one ground via column. In this manner, the ground via columns may provide electromagnetic shielding that reduces interference between nearby signal via columns. This column-based arrangement of PCB vias may also enable more efficient routing of conductive traces away from the PCB vias. For instance, such traces may be routed through an inter-column space between adjacent ground via columns, reducing crosstalk between the conductive traces and nearby PCB signal vias.

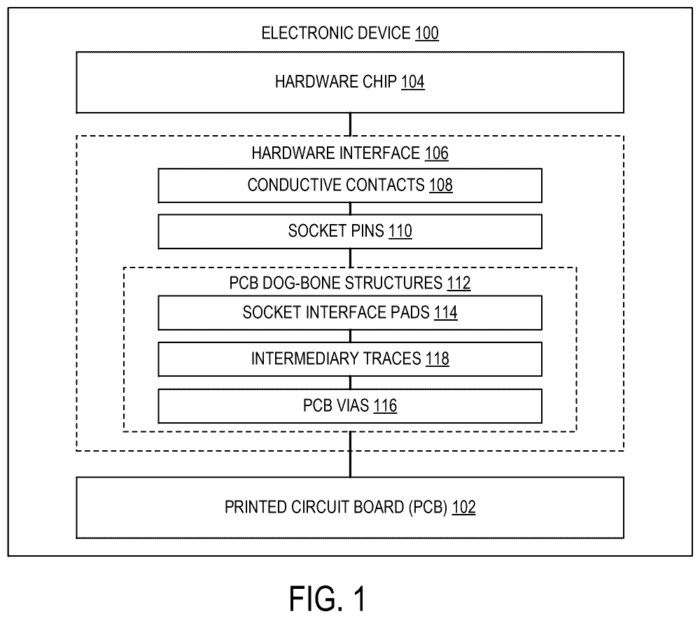

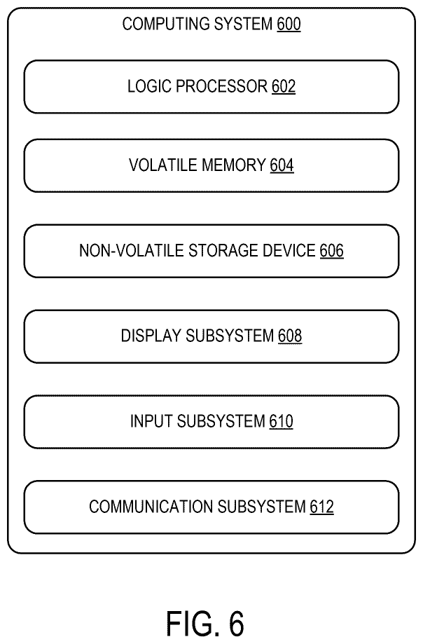

FIG. 1 schematically illustrates an example electronic device 100 that may incorporate the PCB dog-bone arrangements described herein. The electronic device 100 may have any suitable capabilities, hardware configuration, and form factor. For instance, electronic device 100 may take the form of a computing device (e.g., laptop computer, desktop computer, server computer), mobile computing device (e.g., smartphone, tablet), wearable computing device (e.g., smartwatch, mixed reality device), internet-of-things (IoT) device, media streaming device, automotive computing device, etc. As one non-limiting example, electronic device 100 may be implemented as computing system 600 described below with respect to FIG. 6.

Electronic device 100 includes a PCB 102, which is communicatively coupled with a hardware chip 104. The PCB may take any suitable form. For instance, the PCB may include any suitable number of different conductive and non-conductive layers that provide mechanical support and electrical connectivity for components of the electronic device. A PCB may include multiple layers of conductive traces, insulating dielectric materials, plated vias, etc., to facilitate signal routing, power distribution, and/or thermal management.

Similarly, the hardware chip may take any suitable form. As used herein, the term “hardware chip” refers to any suitable integrated circuit (IC) or semiconductor device that interfaces with the PCB through a socketed or soldered hardware interface. A hardware chip may include, but is not limited to, central processing units (CPUs), graphics processing units (GPUs), application-specific integrated circuits (ASICs), field-programmable gate arrays (FPGAs), memory modules such as dynamic random-access memory (DRAM) chips, networking controllers, and other microelectronic components designed to perform computing, data processing, and/or signal transmission functions. In some implementations, the hardware chip includes a land grid array (LGA) package configured to interface with a corresponding LGA socket on the PCB. As additional examples, the hardware chip may utilize a ball grid array (BGA) or pin grid array (PGA) package, or another suitable interface topology. The hardware chip may be implemented as any of the components of computing system 600 described below with respect to FIG. 6.

In FIG. 1, PCB 102 and hardware chip 104 are communicatively coupled via a hardware interface 106. As used herein, the term “hardware interface” refers to a structural and electrical interconnection system that facilitates communication between a hardware chip and a PCB. Though FIG. 1 depicts the hardware interface as being separate from the PCB and the hardware chip, this is done only for the sake of illustration. Rather, it will be understood that the hardware interface comprises several different components, some of which may be attached to/integrated into the hardware chip, and some of which may be attached to/integrated into the PCB. Depending on the implementation, a hardware interface may support various suitable communication standards, such as PCIe (Peripheral Component Interconnect Express), Ethernet, DDR (Double Data Rate) memory buses, and/or serial high-speed interconnects.

In the example of FIG. 1, the hardware interface includes a plurality of conductive contacts 108 on the surface of the hardware chip. In some implementations, these conductive contacts may be arranged in a predefined pattern to facilitate signal transmission, power delivery, and/or electrical grounding. For instance, in some implementations, the arrangement of conductive contacts follows a predefined industry standard, such as those specified for LGA, BGA, or PGA packages, to maintain compatibility with existing socket designs and PCB layouts.

The conductive contacts 108 are aligned with a corresponding set of socket pins 110. In this manner, the plurality of socket pins correspond to the plurality of conductive contacts, such that alignment between the socket pins and conductive contacts communicatively couples the hardware chip with the PCB. The socket pins may have any suitable size, shape, and distribution depending on the implementation. The socket pins may be affixed (e.g., soldered) to either or both of the PCB and the hardware chip. The present disclosure primarily focuses on scenarios where the socket pins are physically affixed to the PCB and removably contact the surface of the hardware chip. For instance, in some implementations, the socket pins are spring-loaded contacts arranged within an LGA socket, where the pins press against corresponding conductive contacts on the hardware chip to form an electrical connection. However, this is non-limiting. In other implementations, the socket pins may be soldered or otherwise attached to the hardware chip, and then removably aligned with contacts and/or inserted into holes on the PCB. For instance, the socket pins may correspond to through-hole receptacles in a PGA socket, designed to receive and electrically interface with protruding socket pins on the hardware chip.

Additionally, in this example, the hardware interface includes a plurality of PCB dog-bone structures 112. The PCB dog-bone structures are used to electrically connect the PCB vias to the corresponding plurality of socket pins. As discussed above, the PCB dog-bone structures each include respective socket interface pads 114 and PCB vias 116, which are connected by intermediary traces 118. The socket pins 110 discussed above are electrically connected (e.g., via soldering) with the socket interface pads. Thus, in some examples, the socket interface pads may be arranged using a distribution pattern that is complementary to the arrangement of conductive contacts on the hardware chip—e.g., consistent with a predefined industry standard. As one non-limiting example, the plurality of socket interface pads may be arranged in a hexagonal grid. This may beneficially preserve compatibility with existing hardware chip designs and standards, while achieving the reduction in signal interference described herein.

The PCB vias take the form of electrically conductive pathways that extend through one or more layers of the PCB to facilitate inter-layer signal routing, power distribution, and/or grounding. PCB vias may include a plated hole surrounded by a conductive via pad, enabling electrical connection between traces on different PCB layers. The techniques described herein may be implemented using any suitable types of PCB vias, such as through-hole vias, blind vias, buried vias, microvias, etc. The PCB vias themselves may be electrically coupled with circuit traces of the PCB, enabling signal and/or power exchange between the hardware chip and various other components or subsystems of the electronic device.

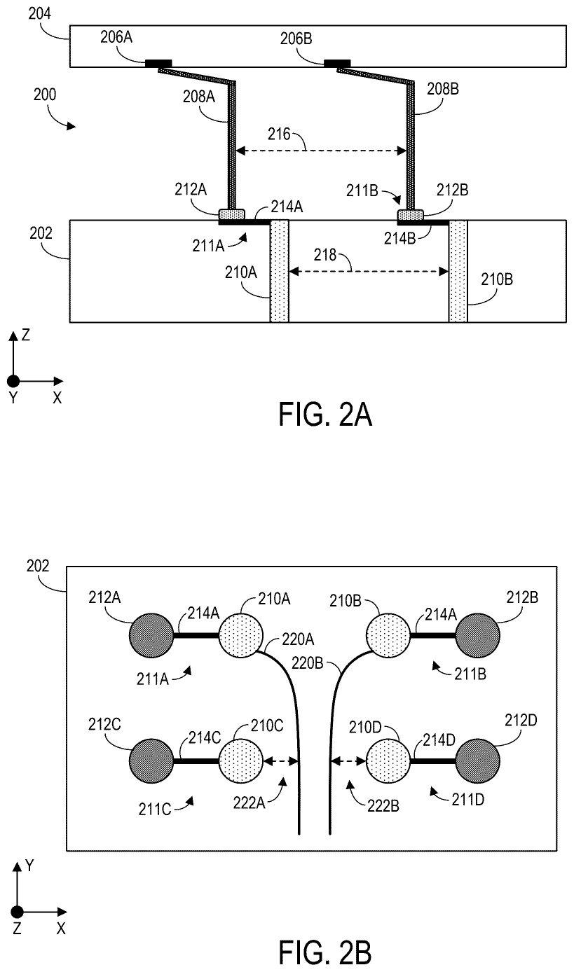

The PCB dog-bone structures will now be described in more detail with respect to FIGS. 2A and 2B. Specifically, FIG. 2A schematically shows a cross-sectional view of an example hardware interface 200, which includes a PCB 202 and a separate hardware chip 204. The hardware chip includes a plurality of conductive contacts, two of which are shown in FIG. 2A as conductive contacts 206A and 206B. These are aligned with corresponding socket pins 208A and 208B. The socket pins extend between the hardware chip and the PCB, and are electrically connected with PCB vias 210A and 210B using PCB dog-bone structures 211A and 211B. As discussed above, the PCB dog-bone structures include socket interface pads 212A and 212B, which are connected to the PCB vias 210A and 210B via corresponding intermediary traces 214A and 214B. In this manner, the PCB dog-bone structures electrically connect the socket pins to the PCB vias.

FIG. 2B provides a different view of PCB 202 and the PCB dog-bone structures 211A and 211B. Specifically, in FIG. 2B, the plane of the PCB is now parallel to the plane of the page (e.g., parallel to the X and Y axes), while the PCB vias now extend into the page (e.g., parallel to the Z axis). In addition to the PCB dog-bone structures 211A and 211B discussed above, in FIG. 2B, the PCB includes PCB dog-bone structures 211C and 211D. These each include respective PCB vias 210C and 210D, connected to socket interface pads 212C and 212D via intermediary traces 214C and 214D. Additionally, in FIG. 2B, the PCB includes circuit traces 220A and 220B, which respectively extend away from PCB vias 210A and 210B. In this manner, the circuit traces may carry signals and/or electrical power between the PCB vias and other components of the electronic device. Similar circuit traces may extend away from PCB vias 210C and 210D, although these are not shown in FIG. 2B.

As discussed above, the proximity between these various different components of the hardware interface can contribute to electromagnetic crosstalk, thereby interfering with the exchange of data between the PCB and hardware chip. For instance, electrical signal moving through one PCB via may generate an electromagnetic field that affects one or more adjacent PCB vias (e.g., via-to-via crosstalk), potentially changing any data signals being carried by the adjacent PCB vias. Similar crosstalk may be exhibited between nearby socket pins (e.g., pin-to-pin crosstalk). These types of crosstalk are each illustrated with respect to FIG. 2A, showing a representation of pin-to-pin crosstalk 216 between socket pins 208A and 208B, and a representation of via-to-via crosstalk 218 between PCB vias 210A and 210B.

Additionally, in some cases, crosstalk may be exhibited between circuit traces on the PCB, and any PCB vias that the circuit traces pass nearby along their routing (e.g., trace-to-via crosstalk). This is schematically illustrated with respect to FIG. 2B, in which the circuit traces 220A and 220B pass near the PCB vias 210C and 210D. This results in trace-to-via crosstalk 222A between circuit trace 220A and PCB via 210C, and trace-to-via crosstalk 222B between circuit trace 220B and PCB via 210D.

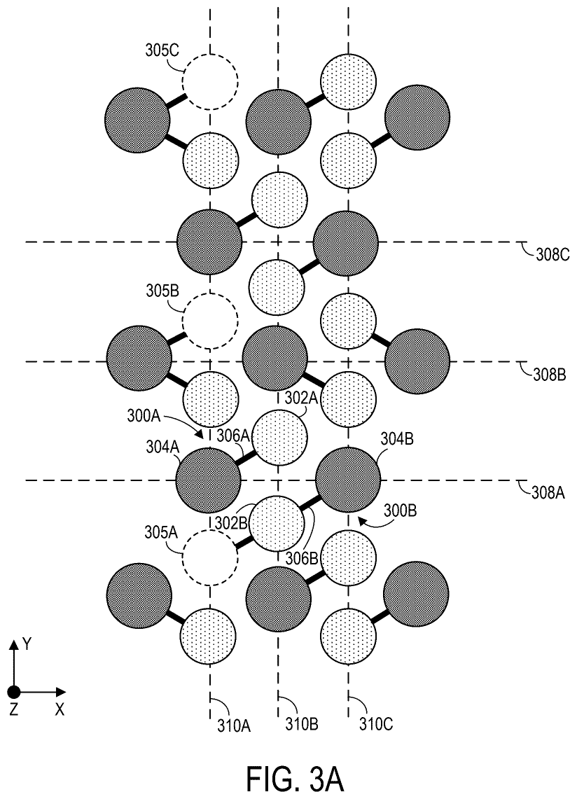

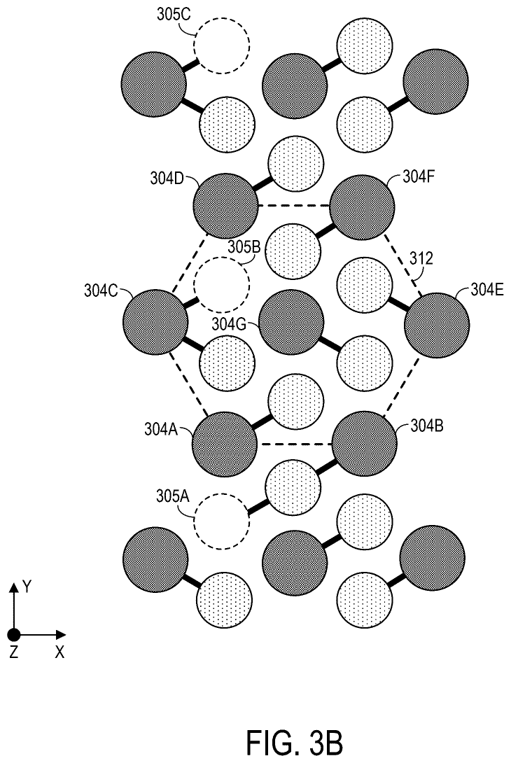

FIGS. 3A and 3B schematically illustrate an example arrangement for the PCB dog-bone structures that may reduce the cumulative signal interference caused by these different sources of crosstalk. Specifically, as will be described in more detail below, the pin-to-pin crosstalk may have the opposite polarity from the via-to-via crosstalk, such that these two types of crosstalk at least partially cancel one another out. In this manner, the cumulative signal interference caused by the different sources of crosstalk is reduced, as compared to other scenarios where the pin-to-pin and via-to-via crosstalk each have the same polarity.

Specifically, FIG. 3A schematically shows a plurality of different PCB dog-bone structures arranged on the surface of a PCB. These include a first PCB dog-bone structure 300A and a second PCB dog-bone structure 300B. The first PCB dog-bone structure includes a first PCB via 302A and a first socket interface pad 304A, connected by a first intermediary trace 306A. The second PCB dog-bone structure includes a second PCB via 302B and a second socket interface pad 304B, connected by a second intermediary trace 306B. As shown, first PCB via 302A is adjacent to second PCB via 302B, meaning these two PCB vias are closer to one another than they are to other PCB vias shown in FIG. 3A. Similarly, the first socket interface pad 304A is adjacent to the second socket interface pad 304B, as they are closer to one another than they are to other socket interface pads on the PCB.

In some implementations, the hardware interface may include additional ground vias used to balance the ground via distribution around signal vias. These are shown in FIG. 3A as additional ground vias 305A, 305B, and 305C. In the case of FIG. 3A, these additional ground vias are attached to adjacent socket interface pads (thereby forming “double dog-bone” structures). In other implementations, the additional ground vias need not be connected to any nearby socket interface pads. In other words, when included, the additional ground vias may or may not be conductively coupled with any socket pins contacting the external hardware chip.

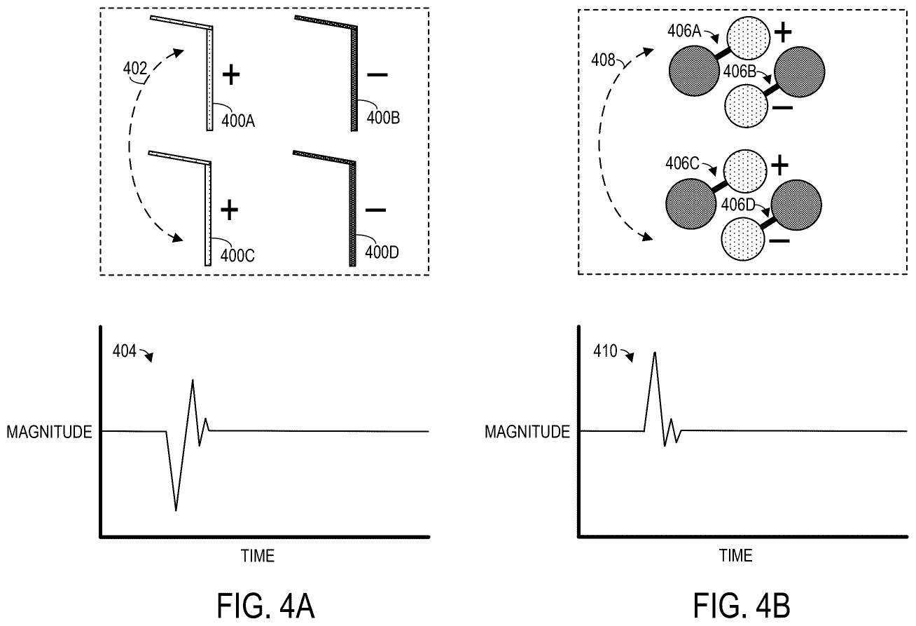

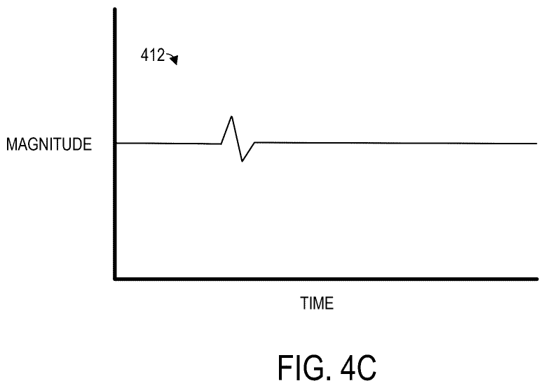

As will be described in more detail below with respect to FIGS. 4A-4C, the first PCB via 302A and second PCB via 302B (along with their corresponding socket pins) may in some cases comprise a differential pair. In other words, in some cases, the first PCB via is configured to propagate an electromagnetic signal having a first polarity, and the second PCB via is configured to propagate a complementary electromagnetic signal having a second polarity, opposite to the first polarity. Differential signaling may be used to reduce noise and signal interference, enabling the receiving circuitry to measure the voltage difference between the two incoming signals rather than the absolute voltage relative to ground. Because the signals are complementary, any external noise coupled onto both conductive interface elements is likely to appear as a common-mode noise. Differential receivers may be used to reject this common-mode noise, extracting only the desired differential signal. Differential signaling, when used with the example arrangements of PCB dog-bone structures described herein, may result in a reduction in cumulative signal interference caused by electromagnetic crosstalk.

Notably, in the arrangement depicted in FIG. 3A, the first socket interface pad and the second socket interface pad are arranged parallel to a first direction. This is indicated by reference line 308A, which extends through the adjacent socket interface pads 304A and 304B, parallel to the X axis as depicted in FIG. 3A. Similar reference lines 308B and 308C are shown for other socket interface pads of the plurality of PCB dog-bone structures.

By contrast, the first PCB via and the second PCB via are arranged parallel to a second direction, different from the first direction. This is indicated by reference line 310B, which extends through adjacent PCB vias 302A and 302B, parallel to the Y axis as depicted in FIG. 3A. Similar reference lines 310A and 310C are shown for other PCB vias of the plurality of PCB dog-bone structures. In other words, reference lines 308A, 308B, and 308C extend in a different direction from reference lines 310A, 310B, and 310C. Furthermore, in this example, the intermediary traces 306A and 306B extend in a third direction, which is different from both the first and second directions. When used in tandem with differential signaling as discussed above, this may bring positive and negative signal vias closer together for tighter capacitive coupling, which can contribute to a reduction in overall signal interference when the via-to-via crosstalk has the opposite polarity from the pin-to-pin crosstalk.

More particularly, in this example, the first direction is perpendicular to the second direction. As such, the socket interface pads 304A and 304B are arranged in a row, and the PCB vias 302A and 302B are arranged in a column, perpendicular to the row. Additionally, in this example, the row is one of two or more rows, and other socket interface pads of the plurality of PCB dog-bone structures are arranged in the two or more rows (e.g., as indicated by reference lines 308A, 308B, and 308C). Similarly, the column of PCB vias is one of two or more columns, and the other PCB vias of the plurality of PCB dog-bone structures are arranged in the two or more columns (e.g., as indicated by reference lines 310A, 310B, and 310C). This stands in contrast to other arrangements, where the socket interface pads and PCB vias are each arranged in rows parallel to one another, and the intermediary traces extend perpendicular to the rows.

It will be understood that the present disclosure is not limited solely to the row/column arrangement depicted in FIG. 3A. Rather, while the PCB vias and socket interface pads are arranged in groups that are aligned in different directions, these directions need not be exactly perpendicular to one another. In other words, while the first and second directions are different (e.g., not parallel to one another), they may have other suitable relationships besides being perpendicular to one another.

As discussed above, in some scenarios, the plurality of socket interface pads may be arranged using a predefined distribution pattern that is consistent with existing standards. For instance, some interface standards may use a hexagonal grid for arranging the socket pins. This may also be referred to as a hexagonal close-packed (HCP) pattern or honeycomb pattern. In such an arrangement, one socket interface pad may be surrounded by six neighboring socket interface pads in a hexagonal layout, increasing pad density while maintaining relatively uniform spacing.

This arrangement is schematically illustrated with respect to FIG. 3B, again showing the plurality of PCB dog-bone structures of FIG. 3A. In FIG. 3B, several of the socket interface pads are labeled as pads 304A, 304B, 304C, 304D, 304E, 304F, and 304G. As shown, socket interface pad 304G is neighbored by the other six socket interface pads 304A-304F, such that the six neighboring pads form a hexagon shape indicated by reference line 312. In this manner, the arrangements described herein may preserve compatibility with existing standards and socket arrangements while still achieving a reduction in signal interference. However, it will be understood that this specific arrangement is non-limiting, and that the socket interface pads may be distributed in other suitable ways, depending on the implementation (e.g., depending on the type of hardware chip that the hardware interface is intended to support).

FIGS. 4A-4C schematically illustrate how the arrangements described herein may result in a reduction to the cumulative signal interference caused by electromagnetic crosstalk. Specifically, FIG. 4A schematically depicts several socket pins, including socket pins 400A, 400B, 400C, and 400D. In this example, the socket pins and their corresponding PCB vias are used to implement differential signaling as discussed above. In other words, as shown, socket pins 400A and 400B form a differential pair, in which pin 400A carries one polarity of the signal (e.g., positive), and pin 400B carries a complementary signal with the opposite polarity (e.g., negative). This is also the case for socket pins 400C and 400D. The proximity of these differential pairs to one another may cause electromagnetic crosstalk as discussed above (e.g., due to capacitive coupling between nearby socket pins), which is represented as pin-to-pin crosstalk 402 in FIG. 4A.

FIG. 4A additionally includes a plot 404, which represents the magnitude of the pin-to-pin crosstalk over time. It will be understood that plot 404, as well as the other plots shown in FIGS. 4B and 4C, is deliberately simplified for the sake of illustration, and is not intended to serve as an accurate representation of crosstalk measured in the real-world. As shown, in this example, the pin-to-pin crosstalk is characterized by an initial spike in the negative direction, followed by subsequent changes in the interference over time. It will be understood that, in other implementations, the pin-to-pin crosstalk may exhibit an initial positive spike, rather than an initial negative spike.

By contrast, FIG. 4B is used to schematically illustrate via-to-via crosstalk. Specifically, FIG. 4B shows four PCB dog-bone structures 406A, 406B, 406C, and 406D. As with the socket pins 400A-400D, the PCB dog-bone structures 406A-406D comprise two differential pairs. PCB dog-bone structures 406A and 406B form one differential pair, while PCB dog-bone structures 406C and 406D form a second differential pair. The proximity of these PCB dog-bone structures together causes via-to-via crosstalk 408.

FIG. 4B additionally includes a plot 410, which represents the magnitude of the via-to-via crosstalk over time. As shown, in this example, the via-to-via crosstalk is characterized by an initial spike in the opposite direction from the spike exhibited by the pin-to-pin crosstalk. In this case, the via-to-via crosstalk exhibits a positive spike and the pin-to-pin crosstalk exhibits a negative spike, although the opposite may occur in other implementations. In this manner, these two types of crosstalk may at least partially cancel one another out.

This is illustrated with respect to FIG. 4C, showing another example plot 412. This represents the cumulative signal interference resulting from the pin-to-pin crosstalk and via-to-via crosstalk together. As shown, the magnitude of the total signal interference is less than the pin-to-pin crosstalk shown in FIG. 4A, or the via-to-via crosstalk shown in FIG. 4B. This is because the two types of crosstalk have opposite polarity, and thus partially cancel one another out. This effect has been demonstrated using an electromagnetic (EM) modeling tool. For instance, in one simulation, via-to-via crosstalk was measured as −42 dB, and pin-to-pin crosstalk was measured as −47 dB. When combined, due to the cancellation effect, it was observed that the total crosstalk is reduced to −50 dB.

This effect may be at least partially attributable to the arrangement of PCB dog-bone structures shown in FIG. 4B. More particularly, in FIG. 4B, PCB dog-bone structure 406B is proximate to PCB dog-bone structure 406C, and these two structures are used to carry signals having opposite polarities (e.g., negative for PCB dog-bone structure 406B, and positive for PCB dog-bone structure 406C). It has been shown that the polarity of the resulting crosstalk can be flipped by disconnecting the PCB dog-bone structures 406A and 406B, and then rebuilding the PCB dog-bone structures, such that the left-side socket interface pad is connected to the lower PCB via, and the right-side socket interface pad is connected to the upper PCB via. If the PCB dog-bone structures 406C and 406D are unchanged, then this change to the dog-bone structures 406A and 406B reverses the polarity of the resulting crosstalk.

As discussed above, crosstalk may also originate due to the proximity of circuit traces on the PCB to nearby PCB vias (e.g., trace-to-via crosstalk). For instance, as illustrated in FIG. 2B, trace-to-via crosstalk may be caused by the proximity of circuit trace 220A to PCB via 210C, and caused by the proximity of circuit trace 220B to PCB via 210D. The example arrangements described herein may additionally serve to reduce the impact of this source of crosstalk.

For instance, as described with respect to FIG. 3A, the PCB vias may be arranged in a plurality of different columns. Furthermore, the PCB vias may include both signal vias (e.g., those used to carry signals to and/or from socket pins), as well a ground vias (e.g., those used to establish an electrical grounding path). The PCB vias may be arranged such that some via columns include two or more signal vias (referred to as “signal via columns”) and other via columns include two or more ground vias (referred to as “ground via columns”). Each signal via column may be neighbored by one or more ground via columns.

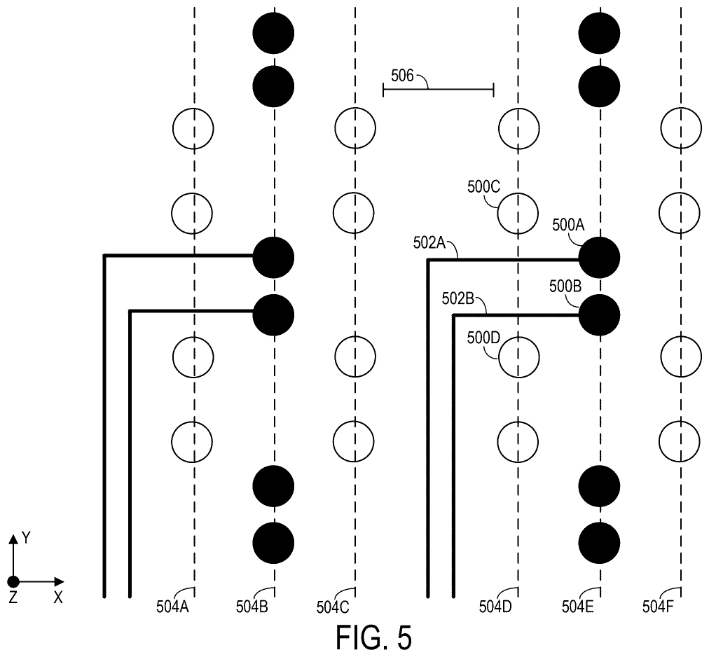

This arrangement is schematically illustrated with respect to FIG. 5, showing a plurality of PCB vias. Four of these PCB vias are labelled as PCB vias 500A, 500B, 500C, and 500D. In FIG. 5, other elements of the PCB dog-bone structures (e.g., the socket interface pads and intermediary traces) are omitted for visual clarity. However, if depicted, the socket interface pads may be arranged in a plurality of rows perpendicular to the PCB via columns, such as is shown in FIGS. 3A and 3B. Furthermore, in FIG. 5, some of the PCB vias are signal vias, represented using black circles, while some of the PCB vias are ground vias, represented using white circles. In other words, PCB vias 500A and 500B are each signal vias, while PCB vias 500C and 500D are both ground vias.

The PCB vias of FIG. 5 are distributed between a plurality of different columns, labeled as columns 504A-504F. These include signal via columns 504B and 504E, along with ground via columns 504A, 504C, 504D, and 504F. With respect to ground via column 504D, the ground via column is separated from a second ground via column 504C by an inter-column space 506. In this manner, the columns of PCB vias may be arranged in sets of three, with each set including a signal via column neighbored by two ground via columns. Each set of three columns is separated by an inter-column space, such as inter-column space 506 shown in FIG. 5. This increases the separation between each column of signal vias, and furthermore, the ground via columns provide an electromagnetic shielding effect. This may serve to reduce or eliminate crosstalk that could otherwise occur between different signal via columns, if such columns were closer together and were not separated by ground via columns.

Furthermore, this arrangement may enable more efficient routing of circuit traces away from the PCB vias. In FIG. 5, circuit traces 502A and 502B each extend away from the signal vias 500A and 500B, and are routed through the inter-column space 506. This may increase the overall distance between the circuit traces and the PCB vias, reducing or eliminating the trace-to-via crosstalk. Furthermore, the inter-column space may enable the use of wider circuit traces, which can reduce signal loss and improve impedance control.

Additionally, or alternatively, this arrangement may enable pairs of circuit traces to be routed closer together. For instance, in some scenarios, adjacent pairs of circuit traces (e.g., representing two differential pairs) may exhibit trace-to-trace crosstalk. Similar to the pin-to-pin crosstalk, the trace-to-trace crosstalk may have the opposite polarity from the via-to-via crosstalk when the PCB dog-bone structure arrangements described herein are used. As such, the trace-to-trace crosstalk may be at least partially cancelled by the via-to-via crosstalk by leveraging the principle of opposite far-end crosstalk polarity. This means that the circuit traces can be routed closer together (e.g., potentially increasing the trace-to-trace crosstalk) without a significant increase in total signal interference, due to opposite polarity cancellation. For instance, using simulations, it has been shown that circuit traces separated by 3 H (where H refers to the dielectric layer thickness) exhibit similar total signal interference to circuit traces separated by 1.5 H, even though the increased proximity of the circuit traces causes increased trace-to-trace crosstalk.

Furthermore, the PCB dog-bone structure arrangements described herein may in some cases contribute to a reduction in cumulative signal interference, even in cases where there is no socket for interfacing with an external hardware chip. In such cases, the total signal interference may be caused both by the via-to-via crosstalk and trace-to-trace crosstalk, in the absence of pin-to-pin crosstalk. However, due to opposite polarity cancellation between the via-to-via crosstalk and trace-to-trace crosstalk, the total signal interference may still be reduced.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 6 schematically shows a non-limiting embodiment of a computing system 600 that can enact one or more of the methods and processes described above. Computing system 600 is shown in simplified form. Computing system 600 may embody the computing system 1 described above and illustrated in FIG. 1. Components of computing system 600 may be included in one or more personal computers, server computers, tablet computers, home-entertainment computers, network computing devices, video game devices, mobile computing devices, mobile communication devices (e.g., smartphone), and/or other computing devices, and wearable computing devices such as smart wristwatches and head mounted augmented reality devices.

Computing system 600 includes a logic processor 602 volatile memory 604, and a non-volatile storage device 606. Computing system 600 may optionally include a display subsystem 608, input subsystem 610, communication subsystem 612, and/or other components not shown in FIG. 6.

Logic processor 602 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors configured to execute software instructions. Additionally or alternatively, the logic processor may include one or more hardware logic circuits or firmware devices configured to execute hardware-implemented logic or firmware instructions. Processors of the logic processor 602 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Non-volatile storage device 606 includes one or more physical devices configured to hold instructions executable by the logic processors to implement the methods and processes described herein. When such methods and processes are implemented, the state of non-volatile storage device 606 may be transformed—e.g., to hold different data.

Non-volatile storage device 606 may include physical devices that are removable and/or built in. Non-volatile storage device 606 may include optical memory, semiconductor memory, and/or magnetic memory, or other mass storage device technology. Non-volatile storage device 606 may include nonvolatile, dynamic, static, read/write, read-only, sequential-access, location-addressable, file-addressable, and/or content-addressable devices. It will be appreciated that non-volatile storage device 606 is configured to hold instructions even when power is cut to the non-volatile storage device 606.

Volatile memory 604 may include physical devices that include random access memory. Volatile memory 604 is typically utilized by logic processor 602 to temporarily store information during processing of software instructions. It will be appreciated that volatile memory 604 typically does not continue to store instructions when power is cut to the volatile memory 604.

Aspects of logic processor 602, volatile memory 604, and non-volatile storage device 606 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 600 typically implemented in software by a processor to perform a particular function using portions of volatile memory, which function involves transformative processing that specially configures the processor to perform the function. Thus, a module, program, or engine may be instantiated via logic processor 602 executing instructions held by non-volatile storage device 606, using portions of volatile memory 604. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

When included, display subsystem 608 may be used to present a visual representation of data held by non-volatile storage device 606. The visual representation may take the form of a graphical user interface (GUI). As the herein described methods and processes change the data held by the non-volatile storage device, and thus transform the state of the non-volatile storage device, the state of display subsystem 608 may likewise be transformed to visually represent changes in the underlying data. Display subsystem 608 may include one or more display devices utilizing virtually any type of technology. Such display devices may be combined with logic processor 602, volatile memory 604, and/or non-volatile storage device 606 in a shared enclosure, or such display devices may be peripheral display devices.

When included, input subsystem 610 may comprise or interface with one or more user-input devices such as a keyboard, mouse, touch screen, camera, or microphone.

When included, communication subsystem 612 may be configured to communicatively couple various computing devices described herein with each other, and with other devices. Communication subsystem 612 may include wired and/or wireless communication devices compatible with one or more different communication protocols. As non-limiting examples, the communication subsystem may be configured for communication via a wired or wireless local- or wide-area network, broadband cellular network, etc. In some embodiments, the communication subsystem may allow computing system 600 to send and/or receive messages to and/or from other devices via a network such as the Internet.

In an example, a hardware interface comprises: a printed circuit board (PCB), including a plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins; wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via; and wherein the first socket interface pad and the second socket interface pad are arranged parallel to a first direction, and the first PCB via and the second PCB via are arranged parallel to a second direction, different from the first direction. In this example or any other example, electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk. In this example or any other example, the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity. In this example or any other example, the first PCB dog-bone structure includes a first intermediary trace connecting the first socket interface pad to the first PCB via, and wherein the first intermediary trace extends in a third direction, different from the first direction and the second direction. In this example or any other example, the first direction is perpendicular to the second direction, such that the first socket interface pad and the second socket interface pad are arranged in a row, and the first PCB via and the second PCB via are arranged in a column that is perpendicular to the row. In this example or any other example, the row is one of two or more rows, and the plurality of PCB dog-bone structures includes a plurality of socket interface pads arranged in the two or more rows, and wherein the column is one of two or more columns, and the plurality of PCB vias are arranged in the two or more columns. In this example or any other example, the plurality of PCB vias includes a plurality of signal vias and a plurality of ground vias, wherein the first PCB via and the second PCB via are each signal vias, and the column is a signal via column, and wherein the signal via column is neighbored by a ground via column including two or more ground vias of the plurality of ground vias. In this example or any other example, the ground column is separated from a second ground column by an inter-column space, wherein the first PCB via is connected to a first circuit trace on the PCB, and wherein the first circuit trace is routed through the inter-column space. In this example or any other example, the plurality of PCB dog-bone structures includes a plurality of socket interface pads arranged in a hexagonal grid. In this example or any other example, the plurality of socket pins correspond to a plurality of conductive contacts of an external hardware chip, such that alignment of the plurality of socket pins with the plurality of conductive contacts communicatively couples the external hardware chip with the PCB.

In an example, an electronic device comprises: a hardware chip including a plurality of conductive contacts; and a printed circuit board (PCB) communicatively coupled with the hardware chip via a hardware interface, the hardware interface comprising: a plurality of PCB dog-bone structures on the PCB, the plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins, wherein alignment between the plurality of socket pins and the plurality of conductive contacts communicatively couples the hardware chip with the PCB; wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via; and wherein the first socket interface pad and the second socket interface pad are arranged parallel to a first direction, and the first PCB via and the second PCB via are arranged parallel to a second direction, different from the first direction. In this example or any other example, electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk. In this example or any other example, the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity. In this example or any other example, the first PCB dog-bone structure includes a first intermediary trace connecting the first socket interface pad to the first PCB via, and wherein the first intermediary trace extends in a third direction, different from the first direction and the second direction. In this example or any other example, the first direction is perpendicular to the second direction, such that the first socket interface pad and the second socket interface pad are arranged in a row, and the first PCB via and the second PCB via are arranged in a column that is perpendicular to the row. In this example or any other example, the row is one of two or more rows, and the plurality of PCB dog-bone structures includes a plurality of socket interface pads arranged in the two or more rows, and wherein the column is one of two or more columns, and the plurality of PCB vias are arranged in the two or more columns. In this example or any other example, the plurality of PCB vias includes a plurality of signal vias and a plurality of ground vias, wherein the first PCB via and the second PCB via are each signal vias, and the column is a signal via column, and wherein the signal via column is neighbored by a ground via column including two or more ground vias of the plurality of ground vias. In this example or any other example, the ground column is separated from a second ground column by an inter-column space, wherein the first PCB via is connected to a first circuit trace on the PCB, and wherein the first circuit trace is routed through the inter-column space. In this example or any other example, the plurality of PCB dog-bone structures includes a plurality of socket interface pads arranged in a hexagonal grid.

In an example, a hardware interface comprises: a printed circuit board (PCB), including a plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins, wherein electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk; wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via; wherein the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity; and wherein the first socket interface pad and the second socket interface pad are arranged parallel to a first direction, and the first PCB via and the second PCB via are arranged parallel to a second direction, different from the first direction.

“And/or” as used herein is defined as the inclusive or V, as specified by the following truth table:

| A | B | A ∨ B |
|---|---|---|
| True | True | True |
| True | False | True |
| False | True | True |
| False | False | False |

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A hardware interface, comprising:
a printed circuit board (PCB), including a plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins;
wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via; and
wherein the first socket interface pad and the second socket interface pad are arranged parallel to a first direction, and the first PCB via and the second PCB via are arranged parallel to a second direction, different from the first direction.

2. The hardware interface of claim 1, wherein electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk.

3. The hardware interface of claim 1, wherein the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity.

4. The hardware interface of claim 1, wherein the first PCB dog-bone structure includes a first intermediary trace connecting the first socket interface pad to the first PCB via, and wherein the first intermediary trace extends in a third direction, different from the first direction and the second direction.

5. The hardware interface of claim 1, wherein the first direction is perpendicular to the second direction, such that the first socket interface pad and the second socket interface pad are arranged in a row, and the first PCB via and the second PCB via are arranged in a column that is perpendicular to the row.

6. The hardware interface of claim 5, wherein the row is one of two or more rows, and the plurality of PCB dog-bone structures includes a plurality of socket interface pads arranged in the two or more rows, and wherein the column is one of two or more columns, and the plurality of PCB vias are arranged in the two or more columns.

7. The hardware interface of claim 6, wherein the plurality of PCB vias includes a plurality of signal vias and a plurality of ground vias, wherein the first PCB via and the second PCB via are each signal vias, and the column is a signal via column, and wherein the signal via column is neighbored by a ground via column including two or more ground vias of the plurality of ground vias.

8. The hardware interface of claim 7, wherein the ground column is separated from a second ground column by an inter-column space, wherein the first PCB via is connected to a first circuit trace on the PCB, and wherein the first circuit trace is routed through the inter-column space.

9. The hardware interface of claim 1, wherein the plurality of PCB dog-bone structures includes a plurality of socket interface pads arranged in a hexagonal grid.

10. The hardware interface of claim 1, wherein the plurality of socket pins correspond to a plurality of conductive contacts of an external hardware chip, such that alignment of the plurality of socket pins with the plurality of conductive contacts communicatively couples the external hardware chip with the PCB.

11. An electronic device, comprising:
a hardware chip including a plurality of conductive contacts; and
a printed circuit board (PCB) communicatively coupled with the hardware chip via a hardware interface, the hardware interface comprising:
a plurality of PCB dog-bone structures on the PCB, the plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins, wherein alignment between the plurality of socket pins and the plurality of conductive contacts communicatively couples the hardware chip with the PCB;
wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via; and
wherein the first socket interface pad and the second socket interface pad are arranged parallel to a first direction, and the first PCB via and the second PCB via are arranged parallel to a second direction, different from the first direction.

12. The electronic device of claim 11, wherein electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk.

13. The electronic device of claim 11, wherein the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity.

14. The electronic device of claim 11, wherein the first PCB dog-bone structure includes a first intermediary trace connecting the first socket interface pad to the first PCB via, and wherein the first intermediary trace extends in a third direction, different from the first direction and the second direction.

15. The electronic device of claim 11, wherein the first direction is perpendicular to the second direction, such that the first socket interface pad and the second socket interface pad are arranged in a row, and the first PCB via and the second PCB via are arranged in a column that is perpendicular to the row.

16. The electronic device of claim 15, wherein the row is one of two or more rows, and the plurality of PCB dog-bone structures includes a plurality of socket interface pads arranged in the two or more rows, and wherein the column is one of two or more columns, and the plurality of PCB vias are arranged in the two or more columns.

17. The electronic device of claim 16, wherein the plurality of PCB vias includes a plurality of signal vias and a plurality of ground vias, wherein the first PCB via and the second PCB via are each signal vias, and the column is a signal via column, and wherein the signal via column is neighbored by a ground via column including two or more ground vias of the plurality of ground vias.

18. The electronic device of claim 17, wherein the ground column is separated from a second ground column by an inter-column space, wherein the first PCB via is connected to a first circuit trace on the PCB, and wherein the first circuit trace is routed through the inter-column space.

19. The electronic device of claim 11, wherein the plurality of PCB dog-bone structures includes a plurality of socket interface pads arranged in a hexagonal grid.

20. A hardware interface, comprising:
a printed circuit board (PCB), including a plurality of PCB dog-bone structures electrically connecting a plurality of PCB vias to a corresponding plurality of socket pins, each PCB dog-bone structure including a respective PCB via of the plurality of PCB vias, an intermediary trace, and a socket interface pad electrically connected to a respective socket pin of the plurality of socket pins, wherein electromagnetic activity at the plurality of socket pins causes pin-to-pin crosstalk, and wherein electromagnetic activity at the plurality of PCB vias causes via-to-via crosstalk, and wherein the pin-to-pin crosstalk has an opposite polarity from the via-to-via crosstalk;
wherein the plurality of PCB dog-bone structures includes a first PCB dog-bone structure and a second PCB dog-bone structure, the first PCB dog-bone structure including a first socket interface pad and a first PCB via, and the second PCB dog-bone structure including a second socket interface pad and a second PCB via, wherein the first socket interface pad is adjacent to the second socket interface pad, and the first PCB via is adjacent to the second PCB via;
wherein the first PCB via and the second PCB via collectively comprise a differential pair, such that the first PCB via is configured to propagate an electromagnetic signal having a first polarity, and wherein the second PCB via is configured to propagate a complementary electromagnetic signal having a second polarity, opposite to the first polarity; and
wherein the first socket interface pad and the second socket interface pad are arranged parallel to a first direction, and the first PCB via and the second PCB via are arranged parallel to a second direction, different from the first direction.
